(19) United States
(12) Patent Application Publication
(10) Pub. No.: US 2024/0407271 A1
(43) Pub. Date: Dec. 5, 2024

(54) ROOM-TEMPERATURE SUPERCONDUCTING PHASE INSULATOR, AND LEAKAGE CURRENT INTERRUPTER USING STABILITY OF ANTIPARTICLES

(71) Applicant: Teresa OH, Cheongju-si, Chungcheongbuk-do (KR)

(72) Inventor: Teresa OH, Cheongju-si, Chungcheongbuk-do (KR)

(21) Appl. No.: 18/698,009

(22) PCT Filed: Oct. 5, 2021
(86) PCT No.: PCT/KR2021/013575

§ 371 Date: Apr. 2, 2024

(51) Int. Cl. H10N 60/82; H10N 50/10; H10N 59/00; H10N 60/85; H10N 69/00

(52) U.S. Cl. CPC H10N 60/82; H10N 50/10; H10N 59/00; H10N 60/855; H10N 69/00

(57) ABSTRACT

A phase insulator according to the present invention can generate a spin current from the energy of a dipole composed of a particle and an antiparticle, and energy of the phase insulator is composed with mobility of the particle and stability of the antiparticle. The particle makes a particle velocity of a conductor, and the antiparticle makes stability of the insulator. The stability of the antiparticle becomes different according to the spin current of the phase insulator. Examples of the spin current include a Majorana fermion, a Weyl fermion, a Dirac fermion, and a neutrino, wherein the Dirac fermion has large stability and mobility and is live with a supercurrent. When a leakage current is interrupted using the Dirac fermion, as the quantum efficiency of an electronic circuit enhances, the span of life becomes longer and stability increases. The leakage current always exists in case that no phase insulator is used. The Majorana fermion which is an antiparticle has large stability due to quantum fluctuation but lacks mobility, and the Weyl fermion has mobility but has less stability than that of the Dirac fermion. The Dirac fermion which generates a supercurrent has both large stability and large mobility. The neutrino which is a particulate neutral current lacks stability and shows that mobility is not large. The phase insulator may be treated by a step of carrying out heat treatment after deposition, or the phase insulator may comprise a heat-resisting when applied to the other electronic circuits.

### TECHNICAL FIELD

The present invention relates to a method of interrupting and controlling a leakage current in order to guarantee the stability of an electronic device, and particularly, a leakage current interruption device using a function to interrupt a leakage current fundamentally using spin currents made by antiparticles, and a function of a phase insulator to protect a circuit so that no problems, such as the sudden unintended acceleration of a car, the occurrence of a spark, overheating, the overcharge of a battery, the non-stability of a high-speed supercapacitor, occur.

### BACKGROUND ART

Leakage current results from a problem occurring because a low electric current of ˜nA or below is not sensed, the leakage current exists in most of electronic circuit devices, and the problem of the leakage current should be settled in such a manner as to control a low spin current of ˜nA or below. However, since there is no spin current generation device, and the spin current has a short life although the spin current is generated, the spin current may not cause an electronic circuit device to operate.

A battery bursting phenomenon of an electric car and a leakage current phenomenon of an electronic sensor have been at issue. In general, control of the electronic sensor is performed using a transistor which is a semiconductor. A conventional transistor is a (single directional transistor) having unidirectional transistor directionality because the concentration of impurities and an electron are used. A bidirectional transistor may operate with a spin current and a surface current and may sense a low electric current of ˜nA or below because it is able to control the spin current. An n-type transistor or a p-type transistor having directionality has the fundamental problem of a leakage current. When the transistor cannot control the spin current, the problem of zero point energy leakage (ZPEL) occurs.

Spin occurs due to the confinement of an electron. A quantum phenomenon occurring at the time of the confinement of the electron is spin, and a spin current is made because the spin has electrical charges of −1/2 and +1/2. Due to the spin current, a neutrino, quantum fluctuation, a Majorana fermion, a Dirac fermion, a Weyl fermion, a quantum tunneling phenomenon, and so on show up.

The conventional transistor operates at only threshold voltage or more and has inferior stability because it is not able to control a spin current, and the conventional transistor moves with a direct current (DC) which operates at only the threshold voltage or more. Furthermore, since a low electric current like the spin current may not be measured, the transistor becomes a unidirectional transistor which shows that directionality of a transfer characteristic is determined according to characteristics of a channel, so there is no choice but to use a direct current (DC). When the transistor is not able to make a spin current, no spin current may be controlled, and an electric current generated at only threshold voltage or below has been classified into a leakage current.

However, according to the appearance of a phase insulator, a spin current could be made, and a bidirectional transistor operating with the spin current was founded. There is no need to have a channel layer for the spin current of the phase insulator. Since there is no channel layer, it is that the spin current is observed from the phase insulator. According to the principle of a spin movement, in order to maintain up and down spins stably, an alternating current (AC) power source is necessarily required.

The transistor has switch and amplification functions. The bidirectional transistor does not generate a leakage current because the spin current is used, and the bidirectional transistor generates a supercurrent due to a quantum tunneling phenomenon and has an effect of amplification which is that the spin current fundamentally evolves into a surface current. Negative energy of zero point energy is in relation to repulsive force. The quantum tunneling phenomenon of an on-off characteristic is an energy phenomenon of nature which means repulsive force as spontaneous symmetry breaking, and stability is ensured. In the phase insulator, no Dirac fermion generates a leakage current fundamentally because it becomes a supercurrent by amplification of the spin current.

In many electronic sensors used in electric cars, the conventional transistor is used. Since the conventional transistor cannot control a spin current, the electronic sensors using a direct current (DC) method of sensing a low electric current generate leakage currents and have the problem of zero point energy leakage (ZPEL). A high-voltage charger (a battery of an electric car) is also problematic in that it fails to charge to 100% due to the generation of a leakage current.

In order to guarantee the stability of electronic cars, it is necessary to develop a technology of preventing a leakage current from being generated by controlling a spin current. The technology of controlling a leakage current is a technology of controlling a spin current, and the technology has been studied in the field of a quantum hall effect, a quantum spin hall effect, a quantum anomalous hall effect, a quantum integer hall effect, a quantum fraction hall effect, a phase insulator, spintronics, and so on. The spin current has four kinds, and the problem of a leakage current will be able to be solved if characteristics of four kinds of spin currents are utilized.

### DETAILED DESCRIPTION OF THE INVENTION

### Technical Problem

An object of the present invention is to provide a device of interrupting a leakage current by using stability of a spin current of a Dirac fermion generated by a phase insulator from the charge symmetry of antiparticles and a quantum tunneling phenomenon of room-temperature superconductivity

Also, another object of the present invention is to a method of causing a spin current of the phase insulator to become a surface current and safely making a supercurrent from the surface current.

Also, another object of the present invention is to provide a difference between non-stability of a neutrino caused by a particle from the phase insulator and stability of three kinds of spin currents based on a Majorana fermion, a Weyl fermion, and a Dirac fermion which are antiparticles.

Also, another object of the present invention is to provide a leakage current interruption device capable of driving a circuit which improves stability of an electronic sensor and a battery for an electronic car by providing a method of connecting the spin current of the phase insulator to an alternating current (AC) power source or a direct current (DC) power source and using it.

Also, the other object of the present invention is to provide a heat-resisting plate in order to guarantee stability when a circuit is completed in such a manner as to connect the leakage current interruption device using the phase insulator to an existing application.

### Solution for Solving the Problem

The present invention is a leakage current interruption device of interrupting a leakage current in such a manner as to generate a spin current by using room-temperature superconductivity of a phase insulator, and particularly, a device using the energy law of nature that stability becomes higher naturally because according to the principle of zero point energy which is that capacitance becomes lower continuously, an antiparticle operates with magnetic reluctance, and a quantum tunneling phenomenon, which occurs spontaneously while up and down spins perform a rotary movement, is a charge symmetry phenomenon of the antiparticle and a superconductive characteristic.

In transistor structure in which there is no channel, but only a phase insulator exists, the effect of a spin current according to the present invention may be confirmed in such a manner as to measure the transfer characteristics of drain-source current versus gate-source voltage (Ips-VGs), and the phase insulator shows the characteristic of the spin current of operating in both directions by depending on the characteristic of a spin movement by which an antiparticle rotates. In order to generate the spin current, an alternating current (AC) is required.

Since the spin motion increases as capacitance, which is the amount of an electrical charge of the spin current capable of being grasped by measurement of the capacitance, reduces gradually, the spin current increases. The spin current and the capacitance are in inverse proportion to each other and are observed by a room-temperature superconductivity phenomenon and a quantum spin tunneling phenomenon which show that spontaneous symmetry breaking occurs when up and down spins are on a vertical line while a potential difference caused by a difference in phase occurs continuously because and the up and down spins for performing a rotary movement exist.

An effect of a surface current of the phase insulator may be obtained in such a manner as to measure voltage to current characteristics from two-terminal structure, and cases in which the surface current increases are shown from a neutrino, a Majorana fermion which performs quantum fluctuation, and a Majorana fermion which becomes a supercurrent. The reason why the surface current is shown in only a conduction band in which capacitance is large or a valence band in which capacitance is small is that the moment the surface current is shown is the moment the phase of spin changes. When the capacitance corresponds to an intermediate level, no charge symmetry occurs, and although voltage changes, since the phase of the spin is not reversed, a change of the surface current doesn't occur.

In case that quantum fluctuation occurs, in spite of the smallest capacitance, the surface current is larger than that of a neutrino. In case of the neutrino, capacitance is larger than that shown from the quantum fluctuation, but the surface current reduces than that shown upon the quantum fluctuation because a spin current is very small. In case of a Dirac fermion, since Schottky contact is performed, it may be understood that a surface current of the Dirac fermion in an area in which voltage is smaller than 5 V is smaller than those shown from the quantum fluctuation and the neutrino according to the Schottky contact. In the quantum fluctuation, no Schottky contact occurs, so a surface current in an area in which voltage is 5 V or below is large. It may be understood that The Schottky contact is required in order to generate a supercurrent in an area in which voltage is larger than 5 V. The Schottky contact may be found from the Dirac fermion and a Weyl fermion which are antiparticles. In order to cause charge symmetry, it may be understood that the Schottky contact is required. It may be understood that the charge symmetry is in direct relation with stability, and the stability originates from the Schottky contact.

The spin current of drain-source current versus drain-source voltage (I_{DS}-V_{DS}) increased from the Dirac fermion and the Weyl fermion which are antiparticles. The neutrino shows that the spin current of I_{DS}-V_{DS} is most small because its particle is in a state of being confined. Although the spin current of the Majorana fermion in which quantum fluctuation occurs increases suddenly at low voltage at first, since spin reduces when the voltage increases, the spin current of the I_{DS}-V_{DS} also reduces. the spin current of the I_{DS}-V_{DS} shown in the Dirac fermion in which up and down spins are in a vertical state in 0 V increased more than that of that of the IDS-VDS shown in the quantum fluctuation.

Since electron affinity is large in the phase insulator, the Dirac fermion in which not only capacitance is large but also the spin current and the surface current are large forms a conduction band. What a valence band is s able to be formed is the Weyl fermion which is an antiparticle and has small electron affinity. The neutrino and the quantum fluctuation are neutral, and the Majorana fermion is not able to be a fermi plane because it is an antiparticle and also shows that the spin current is very large. Therefore, it is preferable that the neutrino corresponds to the fermi plane.

### Effect of the Invention

It is effective to enhance stability because no leakage current flows when a control device of fundamentally interrupting a leakage current is additionally connected in series and an alternating current (AC) power source is supplied so that no problems, such as the sudden unintended acceleration of a car, the occurrence of a spark, overheating, the overdischarge of a battery, the non-stability of a high-speed supercapacitor, and so on, occur.

It is effective in that an exothermic phenomenon disappears, the span of life extends, and stability is improved because a phase insulator based on an AC power source is used so that stability can be ensured, and the mobility of electrons increases as heat resistance reduces through a circuit design based on a direct current (DC) power source, and no leakage current is also generated.

Since vacuum energy of the phase insulator has good electron affinity, the phase insulator operates with a spin current at low voltage and with a surface current at high voltage, it is effective to spontaneously generate an exchange of the spin current for the surface current, so there is no need to have an additional circuit constitution to match the spin current and the surface current, and the circuit constitution of electronic parts gets simple.

It is effective in that the phase insulator can control the spin currents of a Majorana fermion, a Weyl fermion, a Dirac fermion, and a neutrino and can interrupt leakage currents.

It is effective in that the phase insulator can control a spin current and can interrupt a leakage current thanks to charge symmetry of the Majorana fermion, the Weyl fermion, and the Dirac fermion which are antiparticles. Accordingly, it is effective in that stability increases as quantum efficiency enhances. Since the Dirac fermion composed of a pure spin current becomes a supercurrent, it is effective in that stability gets most large.

Since a surface current of the Weyl conductor shows parity symmetry, it fails to become a supercurrent, so an exothermic phenomenon may occur due to the inconsistency of resistance, but this can be solved using a heat-resisting plate, and although the exothermic phenomenon occurs, the spin current can be controlled, so it is effective in that stability enhances because a leakage current is prevented from being generated.

It is effective in that the spin current of a neutrino shown as the effect of particle confinement protects a lower circuit step in such a manner as to reduce a surface current in case that an excess current, like the stroke of lightning, flows suddenly due to inferior stability.

### BRIEF DESCRIPTION OF THE DRAWINGS

FIG. 1 shows each relation between the charge symmetry of antiparticles and the stability of spin currents caused by quantum fluctuation.

FIG. 2 shows each relation between spontaneous symmetry breaking and the charge symmetry of antiparticles due to dependency on the temperature of vacuum energy.

FIG. 3 shows each generation of spin currents by a potential barrier of a phase insulator.

FIG. 4 shows each relation between a spin current and capacitance.

FIG. 5 shows the charge symmetry and capacitance of antiparticles.

FIG. 6 shows each relation between a surface current and capacitance.

FIG. 7 shows each relation between a surface current and a supercurrent.

FIG. 8 shows each relation between a fermion and a supercurrent.

FIG. 9 is a plane view intended for exemplifying one embodiment of a leakage current interruption device using a phase insulator from which a fermions and a surface current are generated.

FIG. 10 is a plane view intended for exemplifying an embodiment of the phase insulator which comprises a heat-resisting plate, and in which a large number of electrodes are arranged in a straight line in order to amplify a surface current.

FIG. 11 is a plane view intended for exemplifying another embodiment of the multi-layered phase insulator intended for amplifying a spin current and arranged vertically

FIG. 12 shows structure of the phase insulator in which a large number of electrodes are disposed in a straight line in order to amplify a surface current.

FIG. 13 shows structure of the phase insulators intended for amplifying a spin current and arranged in multi-layers.

FIG. 14 is a circuit diagram which exemplifies the other embodiment of a leakage current interruption device.

### BEST MODE FOR CARRYING OUT THE INVENTION

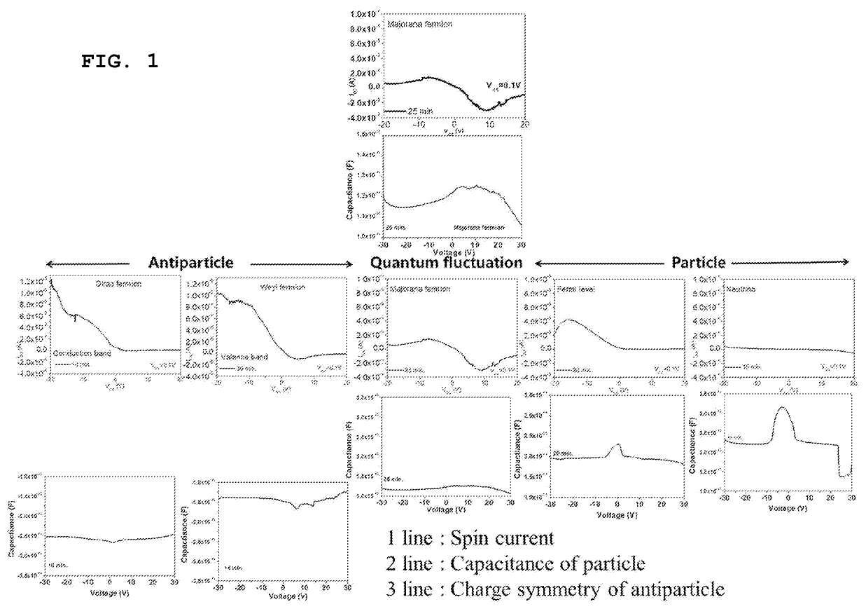

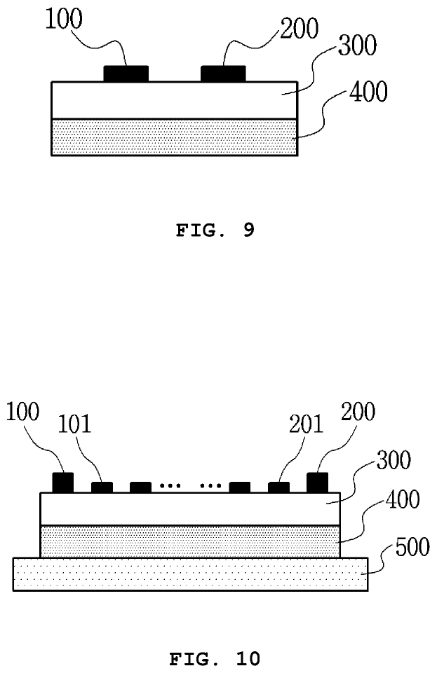

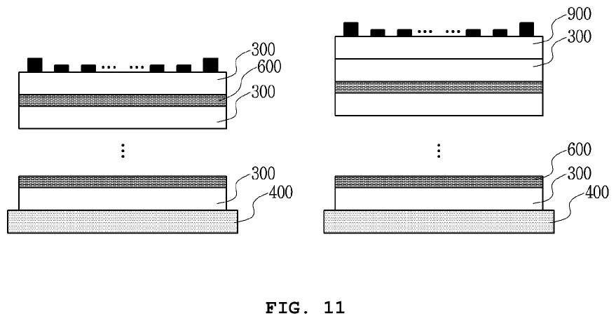

As seen from FIG. 1, the present invention is characterized by a leakage current interruption device using a phenomenon of the charge symmetry of a room-temperature superconduction phase insulator which has electrical characteristics: capacitance is ˜uF or below; an electric current is ˜nA or below; a dielectric constant is 2.0 or below; or heat treatment is required to be performed at temperatures between 50° C. and 400° C., and which generates a spin current based on a Dirac fermion, a supercurrent. Basic circuit structure is characterized by a leakage current interruption device as shown in FIG. 9 or FIG. 11, and in case that a heat-resisting plate is required, the basic circuit structure is characterized by a leakage current interruption device having structure as shown in FIG. 10.

In order to guarantee stability, charge symmetry should occur wherein the charge symmetry occurs from antiparticles, a Dirac fermion and a Weyl fermion, and the Dirac fermion is most excellent with respect to stability thereof. With respect to neutrino which occurs due to the confinement of a particle, no charge symmetry occurs because a characteristic of the particle remains, so stability deteriorates. Examples of a material which can become the phase insulator include, as a general insulator, SiOC and SiO₂, and graphene and a compound semiconductor (IGZO, ZTO, AZO, etc.) which are two-dimensional structure become also the phase insulator when a thin film has thickness of ˜ nm and the structure is amorphous structure.

### MODE FOR CARRYING OUT THE INVENTION

Hereinafter, the preferable exemplary embodiments of the present invention are described in detail with reference to the accompanying drawings. However, the following exemplary embodiments are provided so that the present invention can sufficiently be understood by those having ordinary skill in the technical field, the exemplary embodiments may be modified in various other forms, the scope of the present invention should not be construed as being limited in the exemplary embodiments described below, and the same reference numerals as those presented in in the drawings designate the same constituent elements.

As illustrated in FIG. 1, spin currents are measured at three-terminal structure. In the present invention, a Majorana fermion performs quantum fluctuation (up and down spins) and becomes a positive current at negative voltage, capacitance decreases (up spin), and the Majorana fermion becomes a negative current at positive voltage, and capacitance increases (down spin). The quantum fluctuation forms dipole structure as an antiparticle showing the up spin makes a spin current, and a particle showing the down spin makes a surface current. On the left of the quantum fluctuation are shown the antiparticles, and on the right occur the particles. The antiparticles become spin currents by becoming oscillation energy to provide stability, and the particles become surface currents to provide mobility caused by wave energy. The up spin increases the spin currents and the oscillation energy so that stability becomes higher.

The up and down spins have a dipole form like a proton and an electron, and an antiparticle and a particle, and when an up spin current increases, stability increases, so the up spin current may changes into a surface current and may be a supercurrent. A cause for the occurrence of a leakage current is that mobility increases relatively due to an increase in a down spin current. Capacitance of the up spin which becomes a supercurrent is smaller than that of the down spin. The fact that the capacitance is small means that vacuum energy is large, and the capacitance may be the supercurrent because the vacuum energy is large and the oscillation energy is large.

According to the principle of quantum fluctuation, a Dirac fermion in which capacitance is most small and vacuum energy is large shows that an electric current and the capacitance have symmetrical relation. This is called charge symmetry, and in order to observe the quantum fluctuation of antiparticles (the Dirac fermion and a Weyl fermion), as shown from the bottom of FIG. 1, when capacitance moves symmetrically at right angles, the electric current and capacitance shown from the quantum fluctuation become to have the relation of inverse proportion therebetween.

The examples of spin currents resulting from antiparticles include a Majorana fermion, a Weyl fermion, and a Dirac fermion, and the Dirac fermion is a fermion (a spin current) having the highest stability because there is only a pure spin current, and vacuum energy is most large. Since the Dirac fermion is the spin current which is an antiparticle, it may favorably match with a surface current or a charge current according to the charge symmetry and may also become a supercurrent. Although the Dirac fermion among the antiparticles shows that vacuum energy is large and electron affinity is high, the Weyl fermion shows that electron affinity is low. The Mojorana fermion has no electron affinity because it is neutral according to the quantum fluctuation, so the Mojorana fermion has stability, but no mobility. Since a neutrino resulting from particle confinement has only a surface current without a spin current, it has only mobility without stability, so this becomes the cause for the occurrence of a leakage current.

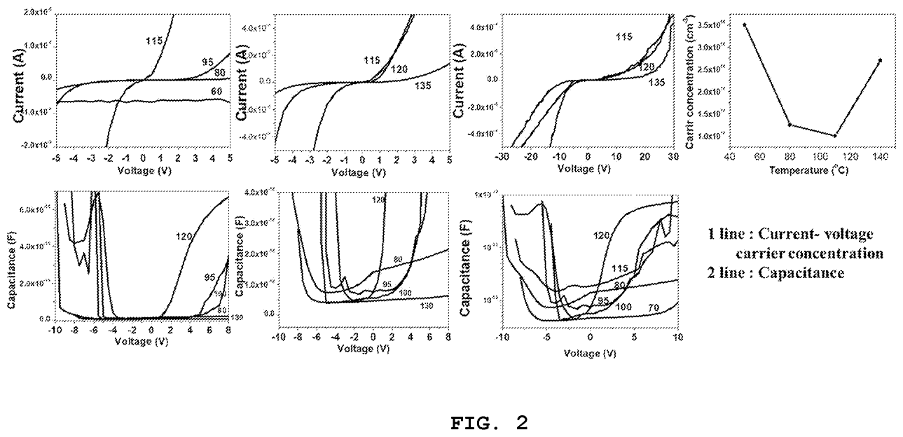

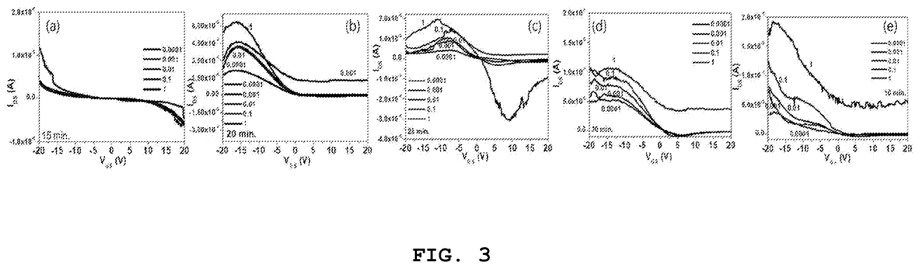

As illustrated in FIG. 2, it shows a result of measurement of surface currents and capacitance obtained from the measurement of two-terminal structure wherein the surface currents and the concentration of a carrier became different according to each temperature for heat treatment. When the heat treatment was performed at 115° C., the carrier concentration was most low, but each surface current increased extremely much, so the surface currents became supercurrents. In addition, the capacitance was also most high in case that heat treatment was performed at 115° C. in an area of −5 V<voltage<+5 V.

The surface current of a phase insulator treated by heat at 120° C., and the surface current of a phase insulator for which heat treatment was performed at 115° C. were almost similar to each other. However, in the area of −5 V<voltage<+5 V, each capacitance showed up completely differently. The capacitance of the phase insulator for which heat treatment was performed at 120° C. was most small, but the capacitance of the phase insulator, which was treated by heat at 115° C. and from which charge symmetry occurred, increased to be most large. The charge symmetry occurred from the phase insulator subjected to heat treatment at 115° C., and as a result, this meant that vacuum energy of the phase insulator subjected to heat treatment at 115° C. was large, a supercurrent was generated according to the effect of an increase in capacitance caused by occurrence of the charge symmetry, and stability also increased.

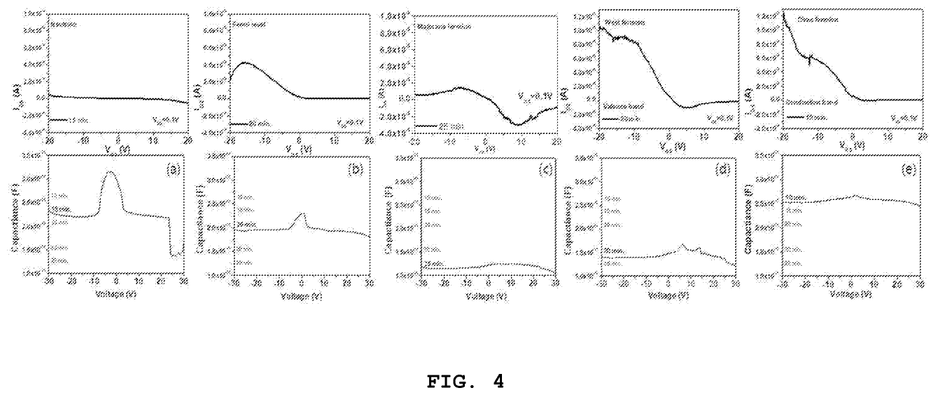

As illustrated in FIG. 4, examples of the spin currents of antiparticles include three kinds of a Majorana fermion, a Weyl fermion, and a Dirac fermion. The antiparticles show that each capacitance moves symmetrically in a vertical direction because charge symmetry operates. According to the charge symmetry of the antiparticles, since the capacitance gets smaller as vacuum energy increases gradually, each capacitance of the Weyl fermion and the Dirac fermion is smaller than that of Majorana fermion, and vacuum energy increases. Accordingly, the capacitance of the Dirac fermion which is live with a supercurrent is most small, vacuum energy is most large, and stability is also most excellent.

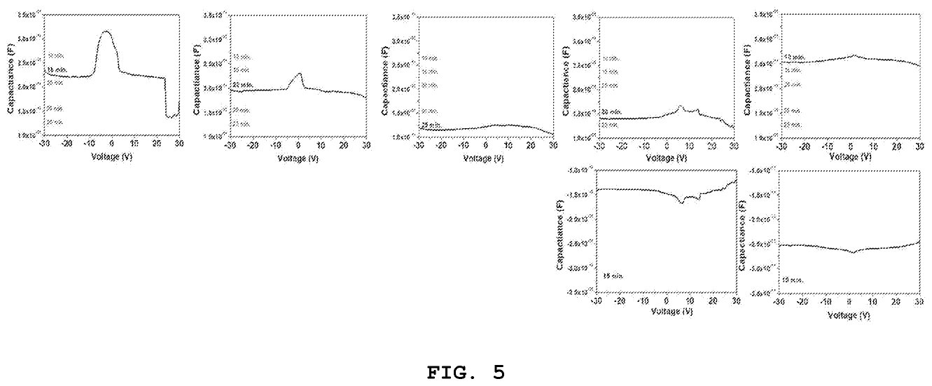

As illustrated in FIG. 5, it represents the charge symmetry of antiparticles. Capacitance reduces in the order of a neutrino, a fermi level, a Majorana fermion from which quantum fluctuation occurs, and a Weyl fermion and a Dirac fermion from which charge symmetry is generated, and at the same time as this, vacuum energy increases.

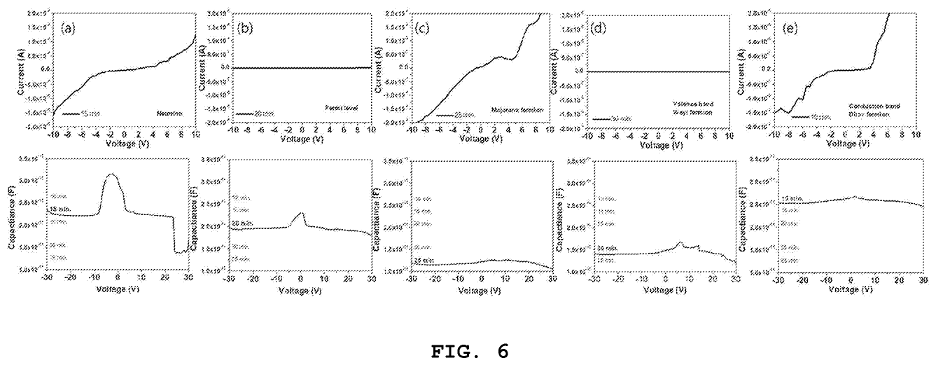

As illustrated in FIG. 6, it shows surface currents and capacitance which can be obtained from two-terminal structure. In the neutrino, the quantum fluctuation, and the Dirac fermion which show that a spin movement becomes stronger, the surface currents increase, and in the fermi level and the Weyl fermion which show that a spin movement becomes weaker, the surface currents decrease. Accordingly, it is shown that spin currents and the surface currents are in proportion to each other. In the neutrino corresponding to the case in which a phase changes, the Mojorana fermion which performs quantum fluctuation, and the Dirac fermion from which charge symmetry occurs, the surface currents showed up.

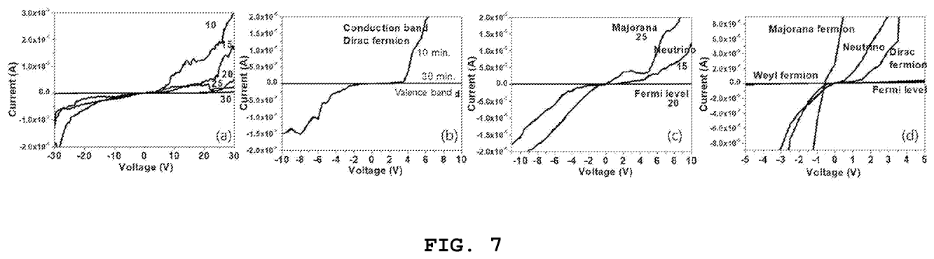

As illustrated in FIG. 7, it shows a comparison among surface current to voltage characteristics, and in a large voltage area, the surface current of the Dirac fermion was most large. In a small voltage area of −5 V<voltage<+5 V capable of confirming Schottky contact, the surface current of the Majorana fermion was most large, but no Schottky contact was generated. Because the Dirac fermion carried out the Schottky contact, the surface current increased suddenly.

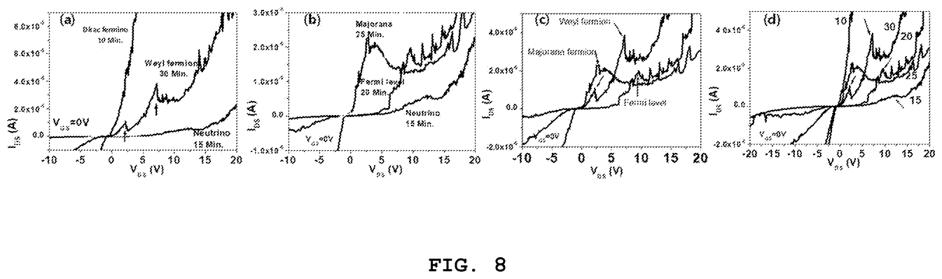

As illustrated in FIG. 8, it may be confirmed that a surface current of the Dirac fermion which carries out Schottky contact in two-terminal structure is most large, and in three-terminal structure, among characteristics of I_{DS}-V_{DS}, since a spin current of the Dirac fermion is most large, a supercurrent is generated from the Dirac fermion. A spin current of the Majorana fermion reduced when voltage increased. A spin current of the Weyl fermion which shows parity symmetry was smaller than that of the Dirac fermion of charge symmetry.

As illustrated in FIG. 9, according to the present invention, a phase insulator is disposed on a substrate 400, and a first terminal 100 and a second terminal 200 are disposed on the phase insulator 300, the phase insulator generates a spin current and produces a surface current, and a transistor of the phase insulator operates in both directions. In the inside of the layer on which the phase insulator 300 is disposed, a spin current flows, and a surface current flows to its surface. With respect to electrode materials of the first terminal and the second terminal, Al, Au, Ag, ITO, and so on in electrode materials used generally are used.

P-type silicon (Si), n-type silicon (Si), ITO glass, polyethylene terephthalate (PET), polyethylene naphthalate (PEN), etc. may be used in a material of the substrate 10. Silicon is mainly used in a basic material at the time of manufacturing of a semiconductor element. On the substrate 400 is formed the phase insulator 300. With respect to materials of the layer on which the phase insulator 300 is disposed, SiOC, SiO₂, Al₂O₃, ZTO, AZO, IGZO, Bi₂Se₃, Bi₂Te₃, Ag₂Te₃, and so on may be used. When the phase insulator has thickness of one atomic layer of 10 nm or below and shows thin amorphous structure, and a dielectric constant is 2.0 or below, as a potential barrier is formed, and vacuum energy is generated, characteristics of the phase insulator show up.

As illustrated in FIG. 10, although no phase insulator generates heat, when it is applied to an application, in case that an exothermic phenomenon occurring due to a leakage current generated from the application and a thermal resistance component has an effect on the phase insulator, in order to prevent the exothermic phenomenon of the phase insulator from occurring, a heat-resisting plate 500 may be used.

As illustrated in FIG. 11, according to the present invention, in order to amplify a low spin current of ˜ρA or below, it is necessary to increase vacuum energy. When the vacuum energy increases in such a manner that a layer showing the structure of a phase insulator/an interlayer conduction film is repeatedly deposited, the spin current may increase. The phase insulator is a thin film of SiOC or SiO₂, and an ITO thin film is used in the interlayer conduction film in order to prevent contamination. A plurality of phase insulators which are multilayered should be thin films of SiOC or SiO₂, and the other phase insulators (a compound semiconductor, ZTO, AZO, and so on) may be used at only the uppermost layer. Graphene is composed of the structure of Al/SiOC/graphene/substrate or Al/SiO₂/graphene/substrate deposited at the lowermost part.

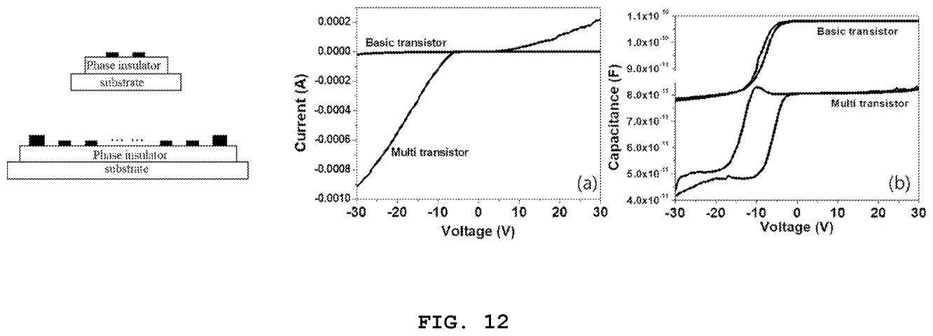

As illustrated in FIG. 12, in the present invention, since the surface current of the phase insulator increases as the surface area widens gradually, when the spin current increases as an electrode is arranged in a straight line, an effect of amplification of the surface current may be obtained accordingly. According to a magnetic reluctance characteristic of the phase insulator and the principle of charge symmetry, it may be confirmed that capacitance reduces when the spin current increases.

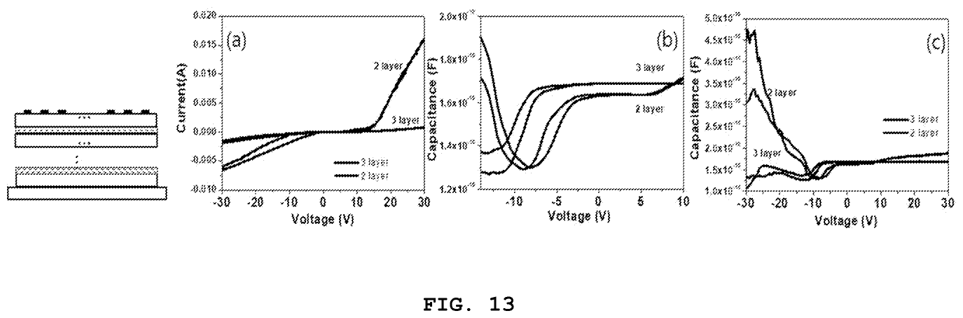

As illustrated in FIG. 13, from the present invention, an effect of the amplification of a spin current may be obtained even though a layer showing the structure of a phase insulator layer/an interlayer conduction film is deposited in multilayers. It may be found that although capacitance reduces at low voltage when a surface current increases, the capacitance also increases when the surface current increases while the principle of the charge symmetry of antiparticles is applied as voltage increases gradually. This principle of the charge symmetry means that the antiparticles show that stability becomes higher and vacuum energy increase as voltage increases gradually, and that supercurrents of the antiparticles using phase insulators are safe.

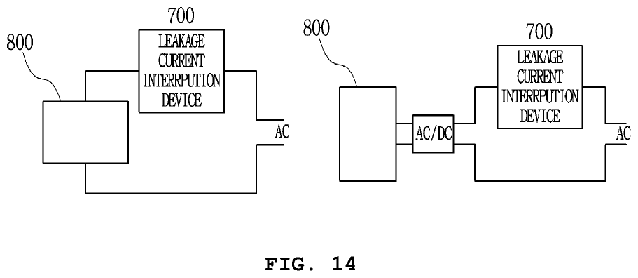

As illustrated in FIG. 14, according to the present invention, a leakage current may be removed using the spin currents of antiparticles, and since the spin currents are maintained at an alternating current (AC) power source, the leakage current interruption device is driven at the (AC) power source, and the stability of an electronic sensor or a battery may be improved using the spin currents, and surface currents of the charge symmetry.

### INDUSTRIAL APPLICABILITY

In an electronic circuit system, there is a leakage current of ˜ nA or below. The leakage current is a cause for the occurrence of problems, such as the sudden unintended acceleration of a car, the occurrence of a spark, overheating, the overcharge of a battery, the non-stability of a high-speed supercapacitor, and so on. It is difficult to measure and to control an electric current of ˜nA or below. However, when the phase insulator is used, a spin current and a surface current may be measured and controlled, so the leakage current may be interrupted. Since the spin current is an electric current resulting from an antiparticle, stability is excellent, so the need for a leakage current interruption safety device has been required as the spread of electronic cars has been increasing gradually. It is easy to produce the leakage current interruption device, a circuit constitution is simple, a Dirac fermion is used, and a supercurrent is generated, so matching with a surface current or a charge current may spontaneously and satisfactorily be realized. In the field of electronic cars and hydrogen cars, its industrial applicability is very wide.

What is claimed is:

1. A leakage current interruption device, which uses a phase insulator,
wherein four kinds of spin currents generated from the phase insulator are a spin current based on a Majorana fermion which performs quantum fluctuation; a neutrino which is a neutral current resulting from a particle effect; and a Dirac fermion and a Weyl fermion as spin currents resulting from antiparticles,
wherein capacitance and the spin current resulting from the quantum fluctuation are in inverse proportion to each other, and
the quantum fluctuation resulting from vacuum energy shows an antiparticle effect (up spin) which is that the spin current increases when the capacitance is small, and a particle effect (down spin) which is that the spin current decreases when the capacitance increases.

2. The leakage current interruption device of claim 1, wherein the phase insulator shows that the Dirac fermion composed of only the spin current which is pure has stability and a characteristic of becoming a supercurrent on the ground that capacitance reduces as the spin current increases gradually because vacuum energy is large, and the Dirac fermion has a superconductive characteristic which is that resistance becomes zero at the room temperature because charge symmetry topologically exists at a Dirac point.

3. The leakage current interruption device of claim 1, wherein the phase insulator shows that the Weyl fermion is composed of the spin current and a surface current, and although the Weyl fermion has an antiparticle (up spin) characteristic which is that capacitance reduces when the spin current increases, stability is inferior than that of the Dirac fermion, so a supercurrent effect caused by the antiparticle reduces relatively, and mobility using the surface current shows up.

4. The leakage current interruption device of claim 1, wherein the phase insulator shows that the neutrino is composed the neutral current resulting from the particle effect, and the neutrino, which has low stability because it is not a spin current, and which is the neutral current, has a characteristic which is that mobility is low because a high electric current flows at low voltage, and a low electric current flows at high voltage.

5. The leakage current interruption device of claim 1, wherein in order to make characteristics of the phase insulator: the concentration of a carrier reduces as vacuum energy increases gradually;
when a spin current is made and voltage increases, the spin current changes into a surface current; and the surface current changes into a supercurrent, the phase insulator is subjected to heat treatment at temperatures between 50° C. to 400° C. after a semiconductor thin-film is deposited, and an insulating material of SiOC and SiO₂ or a compound semiconductor (IGZO, ZTO, AZO, etc.) having characteristics of two-dimensional amorphous structure, which show that capacitance is ˜uF or below, an electric current is ˜nA or below, a dielectric constant is 2.0 or below, and a thin film has thickness of ˜ nm, is used in the phase insulator.

6. The leakage current interruption device of claim 1, comprising:
a substrate;
a layer of the phase insulator located on the substrate;
a first terminal and a second terminal located on the layer of the phase insulator;
a spin current element configured to prevent a leakage current from being generated by making a spin current caused by a potential barrier of a semiconductor thin-film of the phase insulator, a surface area of which is wide and thickness of which is thin, according to a voltage environment of the first terminal and the second terminal, wherein according to voltage applied to an electrode, the spin current changes into the surface current of the phase insulator, and the surface current is amplified into a supercurrent.

7. A leakage current interruption device, comprising:
a first terminal;
a second terminal;
a phase insulator; and
a spin current element configured to prevent a leakage current from being generated by generating a spin current from a potential barrier of the phase insulator according to a voltage environment of the first terminal and the second terminal, wherein the spin current another phase element comprises insulator; a first electrode corresponding to the first terminal and formed on the phase insulator; a second electrode corresponding to the second terminal and formed on the phase insulator to be apart from the first electrode; and spin current electrodes arranged in a line to be apart from one another on the phase insulator between the first electrode and the second electrode, and configured to form multi-electrodes intended for transmitting the spin current, wherein the multi-electrodes amplifies the spin current having directionality according to the voltage environment.

8. The leakage current interruption device of claim 1, further comprising an interlayer conduction film; and an interlayer phase insulator located at a lower part of the interlayer conduction film, and being characterized by an effect which shows that the spin current is amplified when the interlayer conduction film, and the interlayer phase insulator are deposited in one layer or multi layers from a lower part of the phase insulator; and an effect which shows that the phase insulator is not able to be used in the multi-layers laminated when it is a compound semiconductor, an insulating material of SiOC or SiO₂ is able to be used in the multi-layers laminated, and the compound semiconductor is deposited on only the uppermost layer so that the spin current is amplified.

9. The leakage current interruption device of claim 1, wherein the phase insulator operates at an alternating current power source and is combined with a heat-resisting plate adhering to one surface of the substrate on which the phase insulator is formed, and the heat-resisting plate is composed of a metal material.
